(19) United States
(12) Patent Application Publication
(10) Pub. No.: US 2026/0075895 A1
(43) Pub. Date: Mar. 12, 2026

(54) CMOS INTEGRATION OF 2D CHANNEL MATERIALS

(71) Applicant: INTERNATIONAL BUSINESS MACHINES CORPORATION, ARMONK, NY (US)

(72) Inventors: Darsith Jayachandran, Albany, NY (US); Ruilong Xie, Albany, NY (US); Chen Zhang, San Jose, CA (US); Huimei Zhou, Albany, NY (US)

(21) Appl. No.: 18/826,307

(22) Filed: Sep. 6, 2024

(51) Int. Cl. H01L 29/06; H01L 27/092; H01L 29/423; H01L 29/66; H01L 29/775; H01L 29/786

(52) U.S. Cl. CPC H10D 62/121; H10D 30/43; H10D 30/6735; H10D 30/6757; H10D 84/85; H10D 30/014

(57) ABSTRACT

A microelectronic structure that includes a nanosheet FET that includes a plurality of channel layers. Each of the plurality of channel layers includes a bottom layer, a core layer, and a top layer. The bottom layer and the top layer are comprised of a first 2D channel material and the core layer is comprised of a second 2D channel material. The first 2D channel material and the second 2D channel material are different.

### BACKGROUND

The present invention generally relates to the field of microelectronics, and more particularly to the formation of FET that includes 2D channel materials.

Nanosheet is the lead device architecture in continuing CMOS scaling. However, nanosheet technology has shown issues when scaling down such that as the devices become smaller and closer together, they are interfering with each other.

### BRIEF SUMMARY

Additional aspects and/or advantages will be set forth in part in the description which follows and, in part, will be apparent from the description, or may be learned by practice of the invention.

A microelectronic structure that includes a nanosheet FET that includes a plurality of channel layers. Each of the plurality of channel layers includes a bottom layer, a core layer, and a top layer. The bottom layer and the top layer are comprised of a first 2D channel material and the core layer is comprised of a second 2D channel material. The first 2D channel material and the second 2D channel material are different.

A microelectronic structure that includes a first nanosheet FET that includes a plurality of first channel layers. Each of the plurality of first channel layers includes a first bottom layer, a first core layer, and a first top layer. The first bottom layer and the first top layer are comprised of a first 2D channel material and the first core layer is comprised of a second 2D channel material. The first 2D channel material and the second 2D channel material are different. A second nanosheet FET that includes a plurality of second channel layers. Each of the second plurality of channel layers includes a second bottom layer, a second core layer, and a second top layer. The second bottom layer and the second top layer are comprised of the first 2D channel material and the second core layer is comprised of the second 2D channel material.

A microelectronic structure includes a first nanosheet FET that includes a plurality of first channel layers and a first gate. Each of the plurality of first channel layers includes a first bottom layer, a first core layer, and a first top layer. The first bottom layer and the first top layer are comprised of a first 2D channel material and the first core layer is comprised of a second 2D channel material. The first 2D channel material and the second 2D channel material are different. The first gate is in contact with a bottom surface of first bottom layer. A second nanosheet FET that includes a plurality of second channel layers and a second gate. Each of the second plurality of channel layers includes a second bottom layer, a second core layer, and a second top layer. The second bottom layer and the second top layer are comprised of the first 2D channel material and the second core layer is comprised of the second 2D channel material. The second gate is in contact with a top surface and a bottom surface of the second core layer. The second gate is in contact with a side surface of the second bottom layer and a side surface of the second top layer.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of a plurality of the 2D material nanosheet transistors, in accordance with the embodiment of the present invention.

FIG. 2 illustrates cross-sections X1 and X2 of the 2D material nanosheet transistors after the formation of the alternating sacrificial layers and the 2D channel layers, in accordance with the embodiment of the present invention.

FIG. 3 illustrates cross-sections X1 and X2 of the 2D material nanosheet transistors after the formation and processing of the dummy gate and hardmask, and the formation of the gate spacer, in accordance with the embodiment of the present invention.

FIG. 4 illustrates cross-sections X1 and X2 of the 2D material nanosheet transistors after formation of the source/drain or contact region, in accordance with the embodiment of the present invention.

FIG. 5 illustrates cross-sections X1 and X2 of the 2D material nanosheet transistors after recessing of the sacrificial layers, in accordance with the embodiment of the present invention.

FIG. 6 illustrates cross-sections X1 and X2 of the 2D material nanosheet transistors after formation of the inner spacer and formation of the contact component, in accordance with the embodiment of the present invention.

FIG. 7 illustrates cross-sections X1 and X2 of the 2D material nanosheet transistors after formation of an interlayer dielectric layer and the removal of the hardmask, in accordance with the embodiment of the present invention.

FIG. 8 illustrates cross-sections X1 and X2 of the 2D material nanosheet transistors after removal of the dummy gate and the sacrificial layers, in accordance with the embodiment of the present invention.

FIG. 9 illustrates cross-section X1 of the 2D material nanosheet transistors after formation and patterning of a lithography layer and exposing the core layer, in accordance with the embodiment of the present invention.

FIG. 10 illustrates cross-section X2 of the 2D material nanosheet transistors after formation and patterning of a lithography layer and recessing the top layer and bottom layer, in accordance with the embodiment of the present invention.

FIG. 11 illustrates cross-section X1 of the 2D material nanosheet transistors after additional processing, in accordance with the embodiment of the present invention.

FIG. 12 illustrates cross-section X2 of the 2D material nanosheet transistors after additional processing, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings.

These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration. ” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection. ” As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like.

Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed towards a nanosheet transistor where the nanosheets or channel layers are comprised of multiple 2D channel material layers. 2D channel materials can be comprised of any material that can be semiconducting and stable at thicknesses less than 3 nm. For example, the 2D channel materials can be selected from a group consisting of elemental 2D materials—Phosphorene, graphene, etc., transition metal dichalcogenides—MoS₂, WS₂, MoSe₂, WSe₂, MoTe₂, etc., other 2D semiconductors—hBN, etc., or III-VI chalcogenides—MX where M=Ga, In and X=S, Se, Te, Whether the 2D channel materials are a NFET or a PFET depends on the doping of the layers.

The present invention is utilizing multiple 2D channel layers to increase the channel thickness to prevent damage from the process that forms the inner spacer. The multiple 2D channel layers are comprised of a bottom layer, a core layer, and a top layer. The bottom layer and the top layer are comprised of a PFET doped 2D channel material or PFET 2D channel material, and the core layer is comprised of an NFET doped 2D channel material or a NFET 2D channel material. The bottom layer and the top layer can have a thickness in a range of one monolayer to three tri-layers (i.e., three mono-layers thick). The core layer can have a thickness in a range of one monolayer to a tri-layer (i.e., three mono-layers thick). The thickness of the core layer can be the same or different as the bottom and top layers. Utilizing multiple 2D channel layers increases the thickness of the channel layers when compared to a channel layer comprised of only one 2D channel material. The increased thickness of the channel layers prevents the 2D channel layers from being damaged during the formation of the inner spacer.

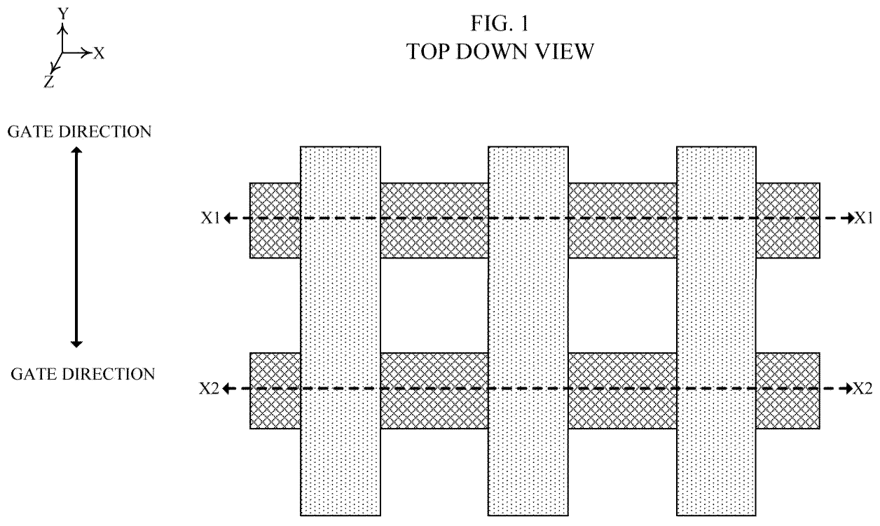

FIG. 1 illustrates a top-down view of multiple 2D channel material nanosheet devices, in accordance with the embodiment of the present invention. The cross-section X1 extends horizontally through the multiple 2D channel material nanosheet transistors. The cross-section X2 extends horizontally through the multiple 2D channel material nanosheet transistors. Cross-section X1 and X2 are perpendicular to the gate direction.

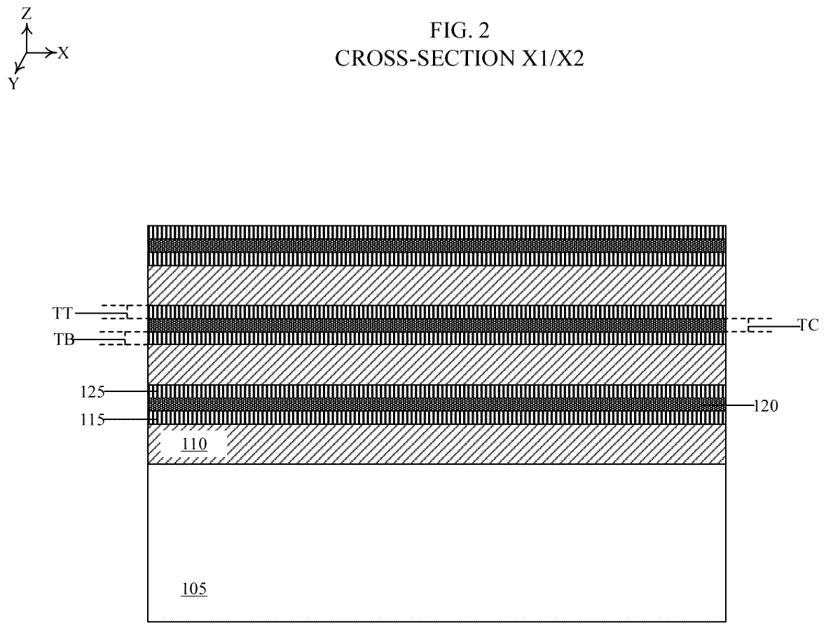

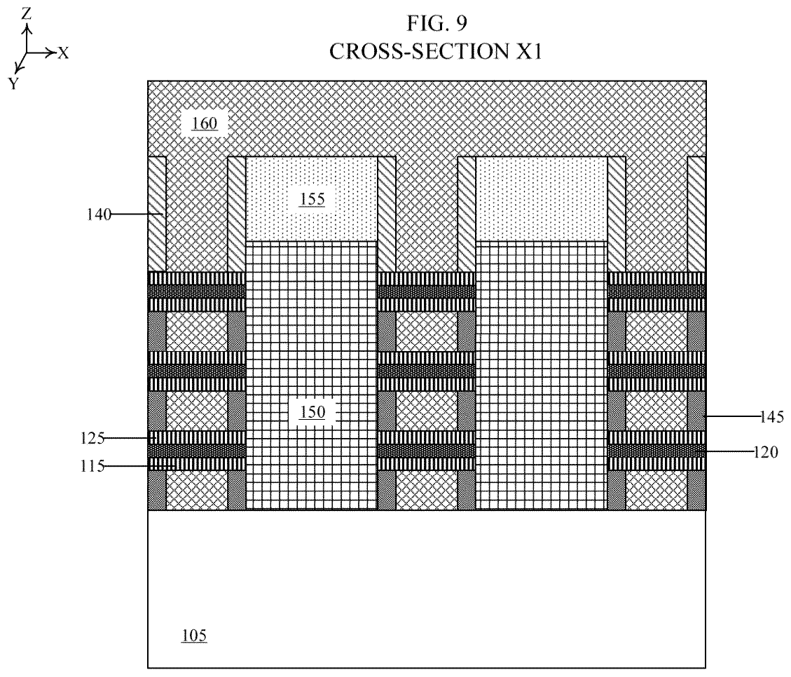

Referring now to FIG. 2, a structure is shown during an intermediate step of a method of fabricating after the formation of the alternating layers that are comprised of sacrificial layers and the 2D channel layers. FIGS. 2-8 illustrate both cross-sections X1 and X2 since their processing has not yet differentiated from each other. FIG. 9-12 illustrates each of the individual cross-sections where the processing differs, which will be described in further detail below.

FIG. 2 illustrates the processing stage after the formation of alternating layers that are comprised of sacrificial layers 110 and the 2D channel layers 115, 120, 125. The alternating layers are formed on top of substrate 105. The substrate 105 can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of semiconductor materials can be used as the semiconductor material of the substrate 105. In some embodiments, substrate 105 includes both semiconductor materials and dielectric materials. The semiconductor substrate 105 may also comprise an organic semiconductor or a layered semiconductor such as, for example, Si/SiGe, a silicon-on-insulator or a SiGe-on-insulator. A portion or the entire semiconductor substrate 105 may also be comprised of an amorphous, polycrystalline, or monocrystalline. Semiconductor substrate 105 may be doped, undoped or contain doped regions and undoped regions therein.

The alternating layers are comprised of alternating sacrificial layers 110 and a 2D material channel. The sacrificial layers 110 can be comprised of, for example, SiGe, where Ge is in the range of about 15 to 30%. Each of the 2D channel layers is comprised of a bottom layer 115, a core layer 120, and a top layer 125. The core layer 120 is located between the bottom layer 115 and the top layer 125. The 2D channel layers are comprised of 2D channel materials. The 2D channel materials can be comprised of any material that can be semiconducting and stable at thicknesses less than 3 nm. For example, the 2D channel materials can be selected from a group consisting of elemental 2D materials—Phosphorene, graphene, etc., transition metal dichalcogenides—MoS₂, WS₂, MoSe₂, WSe₂, MoTe₂, etc., other 2D semiconductors—hBN, etc., or III-VI chalcogenides—MX where M=Ga, In and X=S, Se, Te, Whether the 2D channel materials are a NFET or a PFET depends on the doping of the layers. The bottom layer 115 and the top layer 125 are comprised of a PFET doped 2D channel material or a PFET 2D channel material, and the core layer 120 is comprised of a NFET doped 2D channel material or a NFET 2D channel material. The bottom layer 115 has a thickness TB and the top layer 125 has a thickness TT. The core layer 120 has a thickness TC. Thickness TB and TT are the same value and can be in the range of about one monolayer to a tri-layer (i.e., three mono-layers thick). Thickness TC can be in the range of about one monolayer to a tri-layer (i.e., three mono-layers thick). Thickness TC can be the same as thickness TB and TT or thickness TC can be different than thickness TB and TT. Meaning that thickness TC can be less than, equal to, or greater than thickness TB and TT. By combining NFET (i.e., the core layer 120) and PFET (i.e., the bottom layer 115 and the top layer 125) 2D channel materials together to form a thicker 2D channel layer provides a better junction, better contact, and better process margin during inner spacer formation.

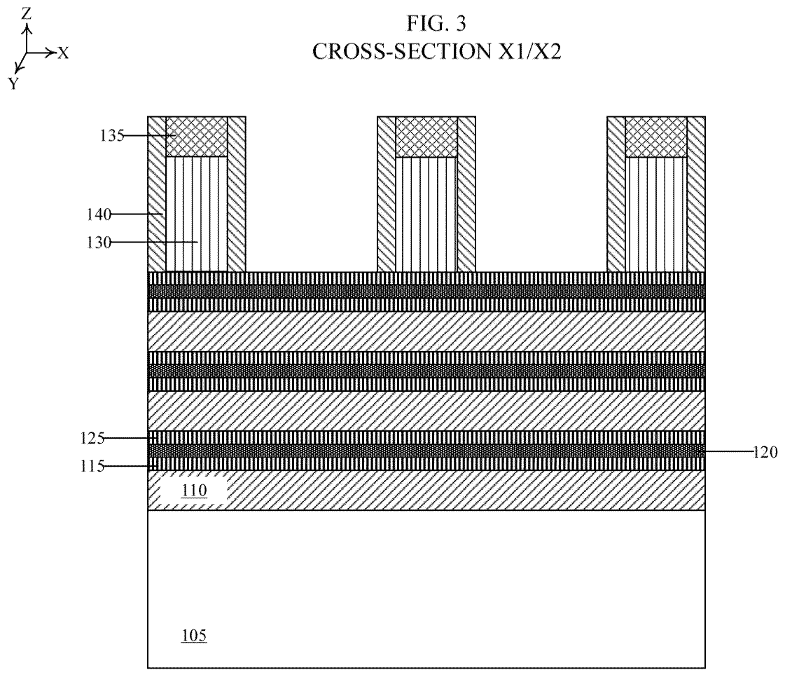

FIG. 3 illustrates the processing stage after the formation and processing of the dummy gate 130 and hardmask 135, and the formation of the gate spacer 140. A dummy gate 130 is formed on top of the top layer of the alternating layers and a hardmask 135 is formed on top of the dummy gate 130. The hardmask 135 and the dummy gate 130 are patterned to form a plurality of columns or gate regions. Gate spacer 140 is formed along the sidewalls of each of the plurality of columns that include the dummy gate 130 and the hardmsk 135.

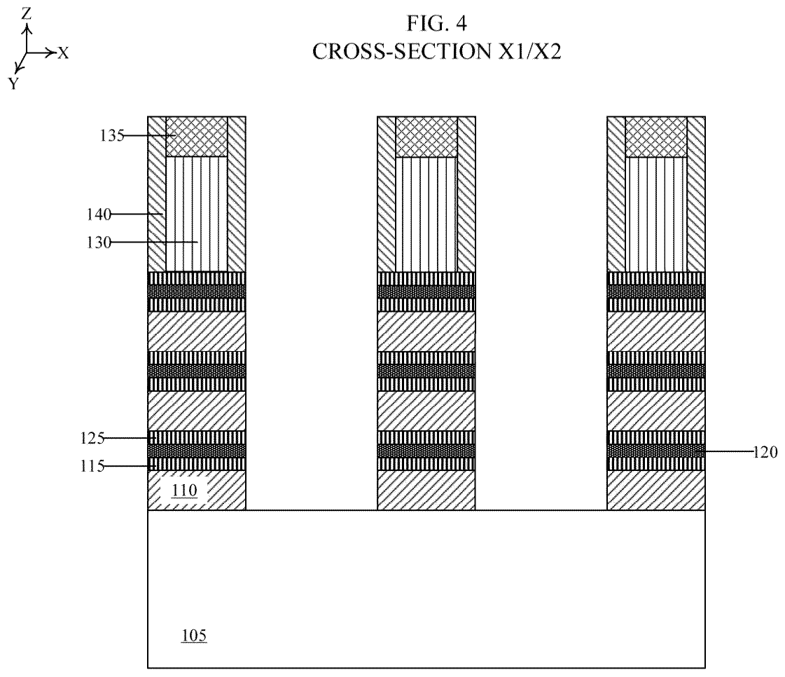

FIG. 4 illustrates the processing stage after formation of the source/drain or contact region. The alternating layers are etched to form a plurality of columns. One of the plurality of columns of the alternating layers is located under one of the columns the of the dummy gate 130, the hardmask 135, and the gate spacer 140. The empty space between the columns will be the source/drain region or a metal contact region.

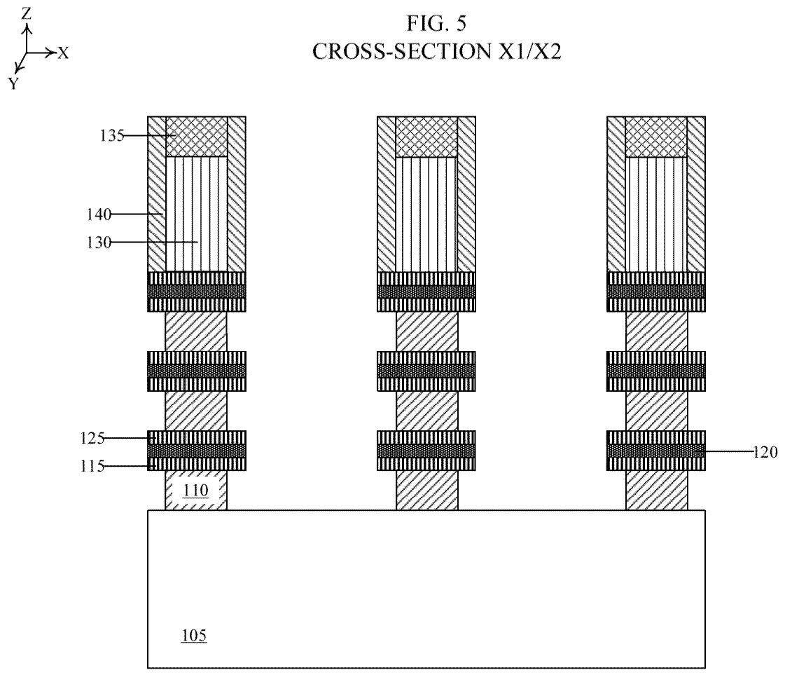

FIG. 5 illustrates the processing stage after recessing of the sacrificial layers 110. The sacrificial layers 110 are recessed to create empty space around the ends or lateral edges of the 2D channel layers (as illustrated in FIG. 5). When the 2D channel layer is comprised of only one layer (i.e., a single layer of PFET or NFET 2D channel material) the relative thinness of this single 2D channel material layer will lead to the 2D channel layer being damaged during the recess process of the sacrificial layers. To prevent this damage the present invention utilizes the combined thickness (i.e., the sum of TB, TT, and TC) of the 2D channel layers (i.e., the bottom layer 115, the core layer 120, and the top layer 125).

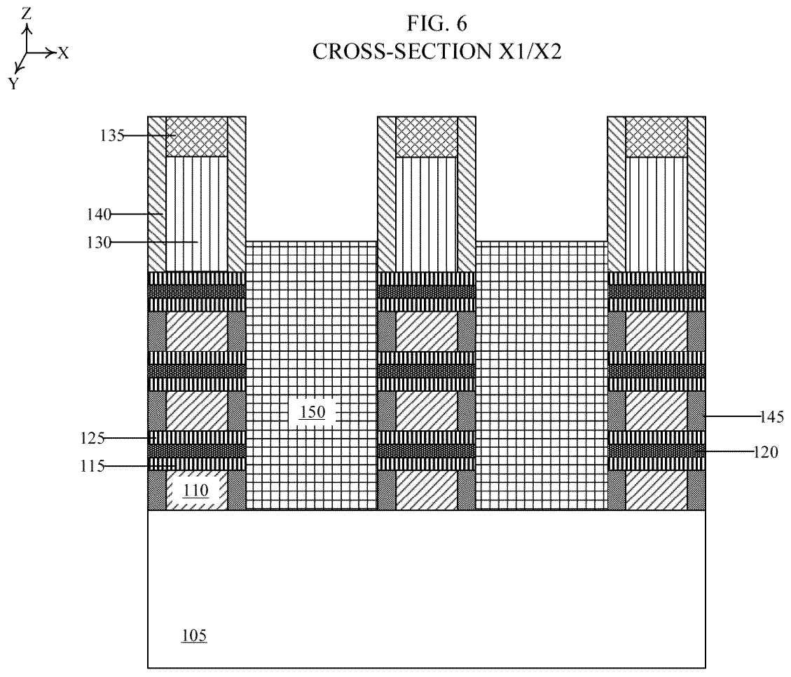

FIG. 6 illustrates the processing stage after formation of the inner spacer 145 and formation of the contact component 150. Inner spacer 145 is formed in the locations where the sacrificial layers 110 were recessed, such that, the inner spacer 145 is located around the ends of the 2D channel material layers. A contact component 150 is formed in source/drain region or the metal contact region located between columns of the alternating layers. The contact component 150 can be a source/drain, a metal contact, or a sacrificial material (which is later replaced with a metal contact or a source/drain).

The contact component 150 can be a source/drain that is comprised of, for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used.

Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques. The contact component 150 can also be other metals like Ni, Ru, palladium, etc. irrespective of whether it is p-type or n-type.

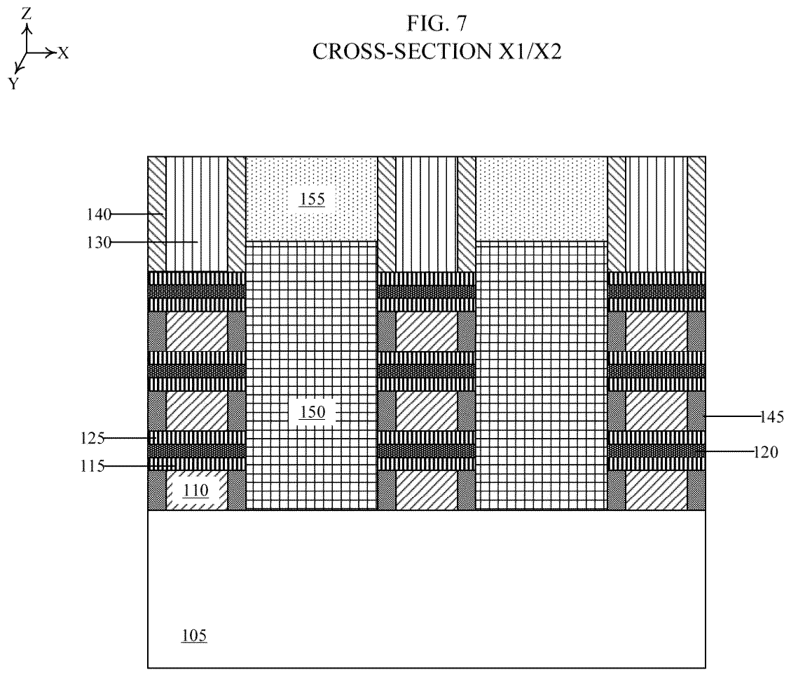

FIG. 7 illustrates the processing stage after formation of an interlayer dielectric layer 155 and the removal of the hardmask 135. An interlayer dielectric layer 155 is formed on top of the contact component 150, on top of the hardmask 135, and on top of gate spacer 140. A planarization process, for example, chemical mechanical planarization (CMP), is utilized to remove excess interlayer dielectric layer 155 material. During the planarization process the hardmask 135 and portions of the gate spacer 145 are removed along with the excess interlayer dielectric layer 155 material.

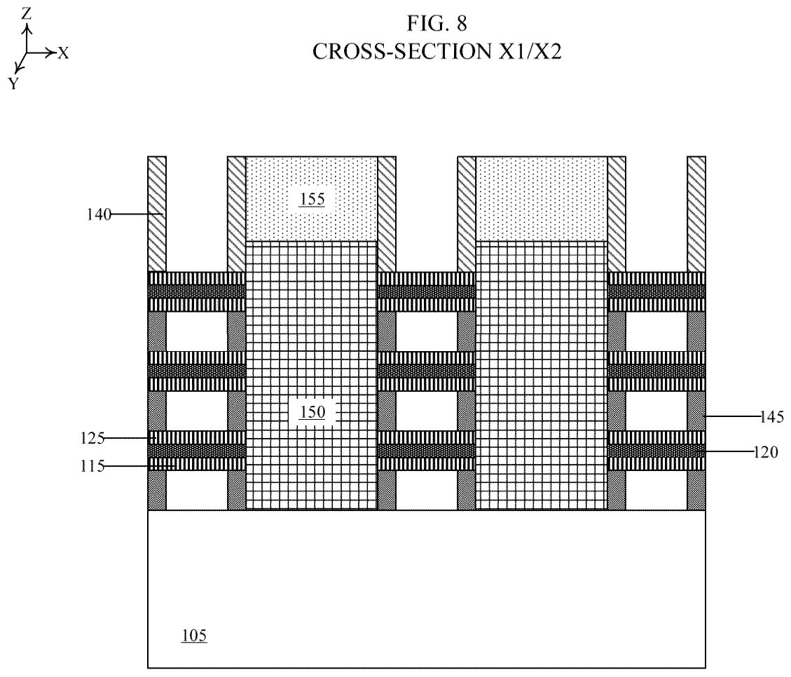

FIG. 8 illustrates the processing stage after removal of the dummy gate 130 and the sacrificial layers 110. The dummy gate 130 and the sacrificial layers 110 are removed from the gate regions. The removal of these layers exposed a portion of the 2D channel layers, e.g., the bottom layer 115 and the top layer 125.

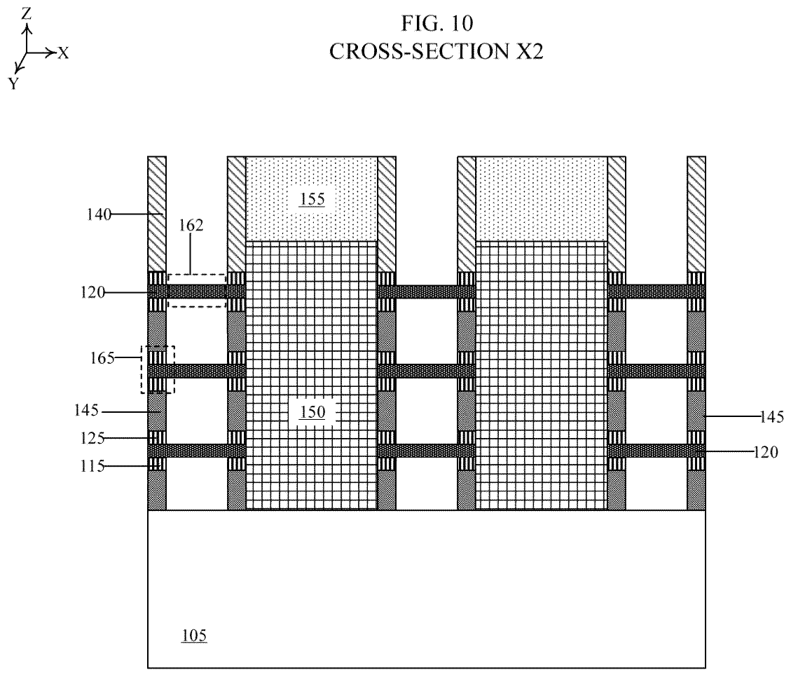

FIGS. 9 and 10 illustrate the processing stage after formation and patterning of a lithography layer 160 and exposing the core layer 120. A lithography layer 160 is formed on top of the 2D material nanosheet transistors devices. The lithography layer 160 is patterned to expose one of the devices while protecting another device, for example, cross-section X1 illustrated in FIG. 9 shows the protected device and cross-section X2 illustrated in FIG. 10 shows the unprotected device. The 2D channel layers (i.e., the bottom layer 115 and the top layer 125) are exposed in the unprotected device. Portions of the bottom layer 115 and the top layer 125 are selectively removed to expose the core layer 120 as emphasized by dashed box 162. A portion of the top layer 125 and the bottom layer 115 remain as emphasized by dashed box 165, where the top layer 125 and the bottom layer 115 remain located vertically above or below the inner spacer 145 or gate spacer 140. The remaining portions of the bottom layer 115 and the top layer 125, as emphasized by dashed box 165, provides support for the exposed core layer 120, which prevents the core layer 120 from collapsing.

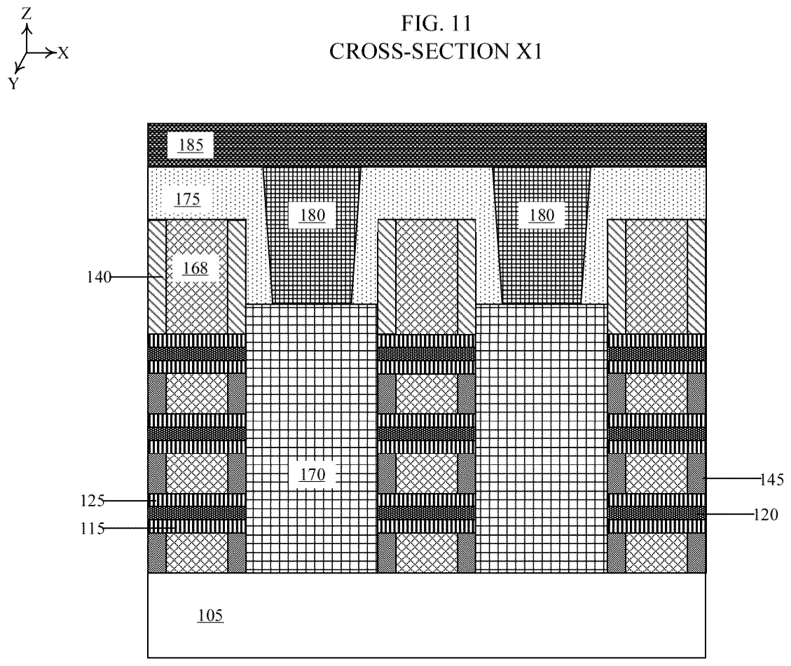

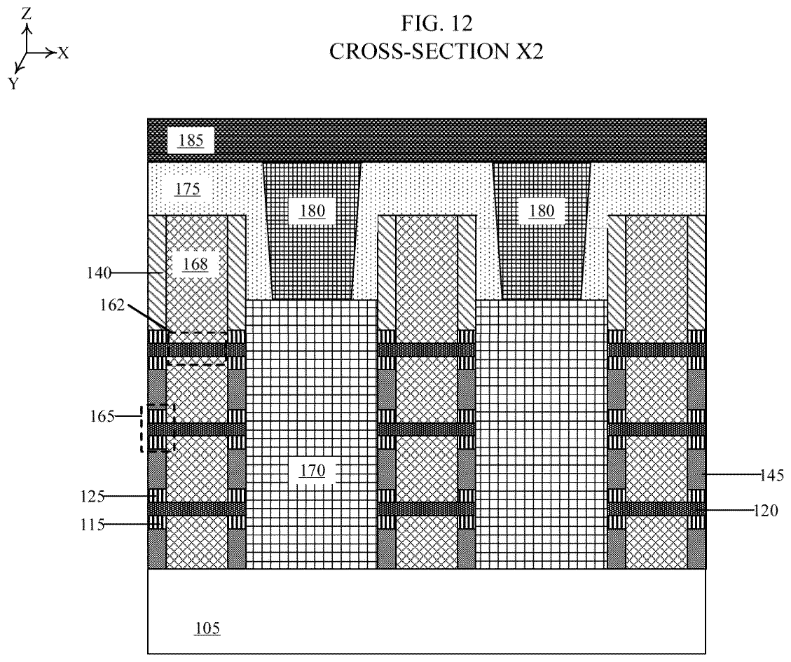

FIGS. 11 and 12 illustrate the processing stage after additional processing. The lithography layer 160 is removed. Gate 168 is formed in the gate regions of the different devices. FIG. 11 illustrates the devices where the top layer 125 and the bottom layer 115 were not removed, such that gate 168 is in contact with a top surface of the top layer 125 and a bottom surface of the bottom layer 115. FIG. 12 illustrates the devices where portions of the top layer 125 and portions of the bottom layer 115 were removed. Gate 168 is in contact with the core layer 120 as emphasized in dashed box 162. Furthermore, gate 168 is in contact with a sidewall of the top layer 125 and a sidewall of the bottom layer 115 as emphasized by dashed box 165. Gate 168 can be comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W.

In the situation where the contact component 150 was comprised of a sacrificial material, then contact component 150 is removed and replaced with component 170. Component 170 can be a conductive metal contact or a source/drain. In response to component 170 being a source/drain then component 170 can be a source/drain that is comprised of, for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

In the situation where the contact component 150 is not comprised of a sacrificial material and is either a conductive metal contact or a source/drain, then contact component 150 and component 170 are the same component with just an updated reference number to reflect the situation where the contact component 150 was comprised of a sacrificial material. When the contact component 150 was comprised of a sacrificial material, then the interlayer dielectric layer 155 was removed during the formation of the contact component 170 and replaced with interlayer dielectric layer 175. When the contact component 150 is not comprised of a sacrificial material, then interlayer dielectric layer 175 and interlayer dielectric layer 155 are the same component. The height of the interlayer dielectric layer 175 is increased to extend over top of gate 168. Trenches (not shown) are formed in interlayer dielectric layer 175, where each of these trenches (not shown) expose a top surface of component 170 or gate 168. These trenches (not shown) are filled with a conductive metal to form component contacts 180 and gate contacts (not shown). The gate contacts (not shown) are located in the gate regions and are in contact with gate 168. An interconnect 185 is formed on top of the interlayer dielectric layer 175, the component contacts 180, and the gate contacts (not shown). Interconnect 185 can be comprised of one or more layers, one or more metal lines, and one or more vias. For simplicity, interconnect 185 is illustrated as a single layer.

A microelectronic structure that includes a nanosheet FET that includes a plurality of channel layers (bottom layer 115, core layer 120, top layer 125, see, for example, FIG. 11). Each of the plurality of channel layers includes a bottom layer 115, a core layer 120, and a top layer 125. The bottom layer 115 and the top layer 125 are comprised of a first 2D channel material and the core layer 120 is comprised of a second 2D channel material. The first 2D channel material and the second 2D channel material are different.

The bottom layer 115 has a first thickness TB, the core layer 120 has a second thickness TC, and the top layer 125 has a third thickness TT.

The first thickness TB, the second thickness TC, and the third thickness TT are equal to each other.

The first thickness TB, and the third thickness TT are equal to each other. The second thickness TC is different than the first thickness TB, and the second thickness TC is different than the third thickness TT.

The first thickness TB is the range of about one monolayer to a trilayer, where the trilayer is equal to three monolayers.

The second thickness TC is the range of about one monolayer to a trilayer, where the trilayer is equal to three monolayers.

The third thickness TT is the range of about one monolayer to a trilayer, where the trilayer is equal to three monolayers.

The first 2D channel material is comprised of PFET material and the second 2D channel material is comprised of a NFET material.

A microelectronic structure that includes a first nanosheet FET that includes a plurality of first channel layers (bottom layer 115, core layer 120, top layer 125, see, for example, FIG. 11). Each of the plurality of first channel layers includes a first bottom layer 115, a first core layer 120, and a first top layer 125. The first bottom layer 115 and the first top layer 125 are comprised of a first 2D channel material and the first core layer 120 is comprised of a second 2D channel material. The first 2D channel material and the second 2D channel material are different. A second nanosheet FET that includes a plurality of second channel layers (bottom layer 115, core layer 120, top layer 125, see, for example, FIG. 12). Each of the second plurality of channel layers includes a second bottom layer 115, a second core layer 120, and a second top layer 125. The second bottom layer 115 and the second top layer 125 are comprised of the first 2D channel material and the second core layer 120 is comprised of the second 2D channel material.

The first nanosheet FET further includes a first gate 168 and the first gate 168 is in contact with a bottom surface of first bottom layer 115. The first gate 168 is in contact with a top surface of the first top layer 125. The first top layer 125 and the first bottom layer 115 prevent the first gate 168 from contacting the first core layer 120.

The second nanosheet FET further includes a second gate 168 (see, for example, FIG. 12). The second gate 168 is in contact with a top surface and a bottom surface of the second core layer 120 (see, for example, FIG. 12).

The first bottom layer 115, the first core layer 120, the first top layer 125, the second bottom layer 115, the second core layer 125, and the second top layer 125 each have a thickness is the range of about one monolayer to a trilayer, where the trilayer is equal to three monolayers.

The first 2D channel material is comprised of PFET material and the second 2D channel material is comprised of a NFET material.

A microelectronic structure includes a first nanosheet FET that includes a plurality of first channel layers (bottom layer 115, core layer 120, top layer 125, see, for example, FIG. 11) and a first gate 168. Each of the plurality of first channel layers includes a first bottom layer 115, a first core layer 120, and a first top layer 125. The first bottom layer 115 and the first top layer 125 are comprised of a first 2D channel material and the first core layer 120 is comprised of a second 2D channel material. The first 2D channel material and the second 2D channel material are different.

The first gate 168 is in contact with a bottom surface of first bottom layer 115. A second nanosheet FET that includes a plurality of second channel layers (bottom layer 115, core layer 120, top layer 125, see, for example, FIG. 12) and a second gate 168. Each of the second plurality of channel layers includes a second bottom layer 115, a second core layer 120, and a second top layer 125. The second bottom layer 115 and the second top layer 125 are comprised of the first 2D channel material and the second core layer 120 is comprised of the second 2D channel material. The second gate 168 is in contact with a top surface and a bottom surface of the second core layer 120. The second gate 168 is in contact with a side surface of the second bottom layer 115 and a side surface of the second top layer 125 (see, for example, FIG. 12, dashed box 165).

The first bottom layer 115, the first core layer 120, the first top layer 125, the second bottom layer 115, the second core layer 120, and the second top layer 125 each have a thickness is the range of about one monolayer to a trilayer, where the trilayer is equal to three monolayers.

The first 2D channel material is comprised of PFET material and the second 2D channel material is comprised of a NFET material.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic structure comprising:
a nanosheet FET that includes a plurality of channel layers, wherein each of the plurality of channel layers includes a bottom layer, a core layer, and a top layer, wherein the bottom layer and the top layer are comprised of a first 2D channel material, wherein the core layer is comprised of a second 2D channel material, wherein the first 2D channel material and the second 2D channel material are different.

2. The microelectronic structure of claim 1, wherein the bottom layer has a first thickness, the core layer has a second thickness, and the top layer has a third thickness.

3. The microelectronic structure of claim 2, wherein the first thickness, the second thickness, and the third thickness are equal to each other.

4. The microelectronic structure of claim 2, wherein the first thickness, and the third thickness are equal to each other.

5. The microelectronic structure of claim 4, wherein the second thickness is different than the first thickness, and the second thickness is different than the third thickness.

6. The microelectronic structure of claim 2, wherein the first thickness is the range of about one monolayer to a trilayer, wherein the trilayer is equal to three monolayers.

7. The microelectronic structure of claim 2, wherein the second thickness is the range of about one monolayer to a trilayer, wherein the trilayer is equal to three monolayers.

8. The microelectronic structure of claim 2, wherein the third thickness is the range of about one monolayer to a trilayer, wherein the trilayer is equal to three monolayers.

9. The microelectronic structure of claim 1, wherein the first 2D channel material is comprised of PFET material and the second 2D channel material is comprised of a NFET material.

10. A microelectronic structure comprising:
a first nanosheet FET that includes a plurality of first channel layers, wherein each of the first plurality of channel layers includes a first bottom layer, a first core layer, and a first top layer, wherein the first bottom layer and the first top layer are comprised of a first 2D channel material, wherein the first core layer is comprised of a second 2D channel material, wherein the first 2D channel material and the second 2D channel material are different; and
a second nanosheet FET that includes a plurality of second channel layers, wherein each of the second plurality of channel layers includes a second bottom layer, a second core layer, and a second top layer, wherein the second bottom layer and the second top layer are comprised of the first 2D channel material, wherein the second core layer is comprised of the second 2D channel material.

11. The microelectronic structure of claim 10, wherein the first nanosheet FET further comprising:
a first gate, wherein the first gate is in contact with a bottom surface of first bottom layer.

12. The microelectronic structure of claim 11, wherein the first gate is in contact with a top surface of the first top layer.

13. The microelectronic structure of claim 12, wherein the first top layer and the first bottom layer prevent the first gate from contacting the first core layer.

14. The microelectronic structure of claim 13, wherein the second nanosheet FET further comprising:
a second gate.

15. The microelectronic structure of claim 14, wherein the second gate is in contact with a top surface and a bottom surface of the second core layer.

16. The microelectronic structure of claim 15, wherein the first bottom layer, the first core layer, the first top layer, the second bottom layer, the second core layer, and the second top layer each have a thickness is the range of about one monolayer to a trilayer, wherein the trilayer is equal to three monolayers.

17. The microelectronic structure of claim 10, wherein the first 2D channel material is comprised of PFET material and the second 2D channel material is comprised of a NFET material.

18. A microelectronic structure comprising:
a first nanosheet FET that includes a plurality of first channel layers and a first gate, wherein each of the first plurality of channel layers includes a first bottom layer, a first core layer, and a first top layer, wherein the first bottom layer and the first top layer are comprised of a first 2D channel material, wherein the first core layer is comprised of a second 2D channel material, wherein the first 2D channel material and the second 2D channel material are different, wherein the first gate is in contact with a bottom surface of first bottom layer; and
a second nanosheet FET that includes a plurality of second channel layers and a second gate, wherein each of the second plurality of channel layers includes a second bottom layer, a second core layer, and a second top layer, wherein the second bottom layer and the second top layer are comprised of the first 2D channel material, wherein the second core layer is comprised of the second 2D channel material, wherein the second gate is in contact with a top surface and a bottom surface of the second core layer, and wherein the second gate is in contact with a side surface of the second bottom layer and a side surface of the second top layer.

19. The microelectronic structure of claim 18, wherein the first bottom layer, the first core layer, the first top layer, the second bottom layer, the second core layer, and the second top layer each have a thickness is the range of about one monolayer to a trilayer, wherein the trilayer is equal to three monolayers.

20. The microelectronic structure of claim 18, wherein the first 2D channel material is comprised of PFET material and the second 2D channel material is comprised of a NFET material.
